(19) United States
(12) Patent Application Publication
(10) Pub. No.: US 2008/0170279 A1
(43) Pub. Date: Jul. 17, 2008

(54) TONE CORRECTION APPARATUS AND IMAGE READING APPARATUS

(76) Inventor: Yuhei KURIGATA, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/951,253

(22) Filed: Dec. 5, 2007

(30) Foreign Application Priority Data
Jan. 15, 2007 (JP) JP2007-005269

(51) Int. Cl. H04N 1/46; G03F 3/08; G06F 15/00

(52) U.S. Cl. 358/525; 358/518; 358/1.9

(57) ABSTRACT

A tone correction apparatus having a look-up table 22 to memorize tone correction data for one sensor chip into one address, a horizontal pixel counter 21 to output designation information of the sensor chip according to a pixel position of input image data in a contact type line image sensor 11, a holding register to hold the tone correction data of one sensor chip read out from the look-up table 22 with reference to the designation information as an address, a selector 24 to select tone correction data of two points, corresponding to a tone value of the input image data in accordance with a selection signal 28 from a comparison section 25, among output from the holding register 23, and interpolation section 26 to perform tone correction of the input image data by linearly interpolating the tone correction data of the aforesaid two points.

This application is based on Japanese Patent Application No. 2007-005265 filed on Jan. 15, 2007, in Japanese Patent Office, the entire content of which is hereby incorporated by reference.

### BACKGROUND OF THE INVENTION

The present invention relates to a tone correction apparatus to correct a tone characteristic of an imaging section and an image reading apparatus therewith, and in particular, to the tone correction apparatus and the image reading apparatus of which processing object is an image data from a imaging section where a plurality of sensor chips having a plurality of imaging elements are arranged.

In the image reading apparatus to read an image using image sensors, to correct the variation of the tone characteristics due to individual differences of the image sensors, some image reading apparatuses carry out tone correction of the image data. For such tone correction, usually used, a look-up table (LUT) where output tone values (tone correction data) after correcting input tone value are memorized. From a view point of the image quality, it is preferred that the look-up table memorizes tone correction data in respect to all the tone values the input image data has. However, in case number of the tone is large, a memory capacity to memorize the look-up table increases. Thus, various technologies where the tone correction data has less number of tonal steps than that of the input image data and the shortage is interpolated by liner approximation are suggested.

For example, as FIG. 13 shows, there is an image reading apparatus where the tone correction data having less number of tonal steps than that of the image to be corrected (for example image data of 256 tonal steps versus 64 tonal steps) is stored in two look-up tables LUT1 and LUT2, and the tone correction data of two points required for linear interpolation is read out from the look-up tables LUT1 and ULT2 in one time to carry out tone correction process as described in Japanese Unexamined Publication 2005-135157 (Hereinafter referred as Patent document 1).

In this apparatus, in two look-up tables LUT1 and LUT2, the same tone correction data are stored, and when the tone correction is carried out, tone correction data (Xn) corresponding to a tone value (Rn) of an input image data is captured from the look-up table LUT1, and at the same time, tone correction data (Xn+1) corresponding to a tone value (Rn+1) of an input image data is captured from the look-up table LUT2 to carry out linear interpolation. As above, since two pieces of the tone correction data necessary for linear interpolation can be referred simultaneously (in one clock), tone correction by linear interpolation is realized without increasing a speed of a read-out clock from the look-up table in respect to an input clock of the image data.

In the above technology, since the memory capacity of the look-up table becomes two times as that of an original capacity, as FIG. 14 shows, in the Patent Document 1 in particular, there is suggested a configuration of a circuit where look-up table LUT1 stores the tone correction data having odd numbers and look-up table LUT2 stores the tone correction data having even numbers, and the output values from the look-up table LUT1 and look-up table LUT2 are replaced each other depending on whether a value of third bit from the lowest bit of input tone value is odd or even and transferred to linear interpolation section so that the tone correction data of two points can be read in one clock without increasing the memory capacity.

In recent years, in the image reading apparatuses sometimes use a contact type line image sensor where a plurality of sensor chips having a plurality of imaging elements are arrayed in a line. In such contact type line image sensor, since the tone characteristics of each of sensor chips are different, a density difference in shape of a line may occur in an outputted image. Such deterioration of image quality can be solved by using individual tone correction data for each sensor chip. However, if the tone correction data for each sensor chip are held for all tonal steps, the memory capacity to store the tone correction data becomes extremely large.

In the technology disclosed in the above Patent Document 1, since the linear interpolation is carried out using tone correction data having less tonal steps than that of the image data, the memory capacity required to hold the tone correction data is reduced. However, since the technology is applied to an image sensor configured with one sensor chip, namely configured with the pixels have substantially the same tone characteristics, the aforesaid density difference in shape of a line cannot be solved when it is applied to the contact type line image sensor configured with the plurality of the sensor chips. Also, it cannot be applied to non-linear interpolation which requires the tone correction data of three or more points.

### SUMMARY OF THE INVENTION

The present invention has been achieved in view of the above problems, to provide a tone correction apparatus and an image reading apparatus where an output image from an imaging section configured by arranging a plurality of sensor chips can be corrected by tone correction with a tone correction characteristic of each sensor chip, and the memory capacity required for holding the tone correction data can be small.

To achieve an object of the present invention, the present invention includes the following.

A tone correction apparatus, including: a correction data memory section to memorize tone correction data having a prescribed tonal steps which is less than that of an image data inputted from imaging elements for each sensor chip of an imaging section where a plurality of the sensor chips having a plurality of the imaging elements are arranged; a designation information generating section to output designation information which designates the sensor chip corresponding to pixel positions of the image data inputted from the imaging elements in the imaging section to the correction data memory section; and a correction section to read out the tone correction data of one sensor chip designated by the designation information outputted from the designation information generating section from the correction data memory section, to interpolate the tone correction data using not less than 2 pieces of tone correction data in the tone correction data of one sensor chip read out, and to carry out tone correction of the image data inputted based on a result of interpolation thereof.

In the above structure, a plurality of sensor chips having a plurality of imaging elements are arranged in the imaging section representing an object of tone correction. The correction data memory section memorizes the tone correction data of all sensor chips of the imaging section in a way that, for example, tone correction data for one sensor chip is memorized so that the number of tonal steps is less than that of the image data in one address. The designation information generating section generates designation information to designates the sensor chip corresponding to the position of the pixel of input image data in the imaging section. The correction section carries out tone correction for the input image data based on the tone correction data for one sensor chip read out from the correction data memory section with reference to the designation information as an address.

In the aforesaid correction section, the tone correction data having less tonal steps than that of the image data is interpolated and based on the result of interpolation the image data is corrected by tone correction. Thereby, the tone steps of the tone correction data to be memorized can be reduced and necessary memory capacity can be reduced. Also based on the designation information, since the tone correction data for one sensor chip is read out, by applying linear interpolation using the tone correction data of two points or non-linear interpolation using the tone correction data of three or more points, tone correction of the image data can be carried out over the whole tonal steps.

An image reading apparatus, having: an imaging section wherein a plurality of sensor chips having a plurality of imaging elements are arranged; an A/D conversion section to convert an analogue image signal outputted from the imaging section to digital image data which is quantized to a prescribed tonal steps; and a tone characteristic correction section to correct tone of the image data outputted from the A/D conversion section, having; a correction data memory section to memorize tone correction data having a prescribed number of tonal steps less than number of tonal steps of the image data of each sensor chips provided in the imaging section, a designation information generating section to output designation information which designates the sensor chips corresponding to positions of pixels of the image data in the imaging section to the correction data memory section,

a correction section to read out the tone correction data of one sensor chip designated by the designation information outputted from the designation information generating section from the correction data memory section, to interpolate the tone correction data using not less than 2 pieces of tone correction data in the tone correction data of one sensor chip read out, and to carry out tone correction of the image data inputted based on a result of interpolation thereof.

In the above invention, a plurality of sensor chips having a plurality of imaging elements are arranged in the imaging section. The correction data memory section memorizes the tone correction data of ail sensor chips of the imaging section in a way that, for example, tone correction data for one sensor chip is memorized so that the number of tonal steps is less than that of the image data in one address. The designation information generating section generates designation information to designates the sensor chip corresponding to the position of the pixel of input image data in the imaging section. The correction section carries out tone correction for the input image data based on the tone correction data for one sensor chip read out from the correction data memory section with reference to the designation information as an address.

In the aforesaid correction section, the tone correction data having less tonal steps than that of the image data is interpolated and based on the result of interpolation the image data is corrected by tone correction. Thereby, the tone steps of the tone correction data to be memorized can be reduced and necessary memory capacity can foe reduced. Also based on the designation information, since the tone correction data for one sensor chip is read out, by applying linear interpolation using the tone correction data of two points or non-linear interpolation using the tone correction data of three or more points, tone correction of the image data can be carried out over the whole tonal steps.

### BRIEF DESCRIPTION OF THE DRAWINGS

FIG. 1 is a block diagram showing a structure of an image reading apparatus related to an embodiment of the present invention.

FIG. 2 is an explanatory diagram of a contact type line image sensor used in an image reading apparatus related to an embodiment of the present invention.

FIG. 3 is a timing chart showing various kinds of signals corresponding to an image reading apparatus related to am embodiment of the present invention.

FIG. 4 is an explanatory diagram showing an exemplary look-up table.

FIG. 5 is an explanatory diagram showing an exemplary compensated tone characteristic obtained by linearly interpolating tone correction data.

FIG. 6 is an explanatory diagram showing an example where an tone value of inputted image data is corrected by tone correction using a compensated tone characteristic after linearly interpolating.

FIG. 7 is an explanatory diagram showing an example of compensated tone characteristic obtained by linearly interpolating tone correction data and tone correction data thereof in case the interpolation tone interval is concentrated to a high brightness side.

FIG. 8 is an explanatory diagram showing an example of an offset compensated tone characteristic.

FIG. 9 is an explanatory diagram showing an example of a compensated tone characteristic in case a difference from a standard tone characteristic represents tone correction data.

FIG. 10 is an explanatory diagram showing an example of a state of operation of a tone characteristic correction section before image data of each front end of line.

FIG. 11 is an explanatory diagram showing an example of a state of operation of a tone characteristic correction section when pixels in a middle portion of a sensor chip are processed.

FIG. 12 is an explanatory diagram showing an exemplary state of operation of a tone characteristic correction section when the last pixel of the sensor chip is processed

FIG. 13 is a block diagram showing an example of a conventional tone compensation circuit.

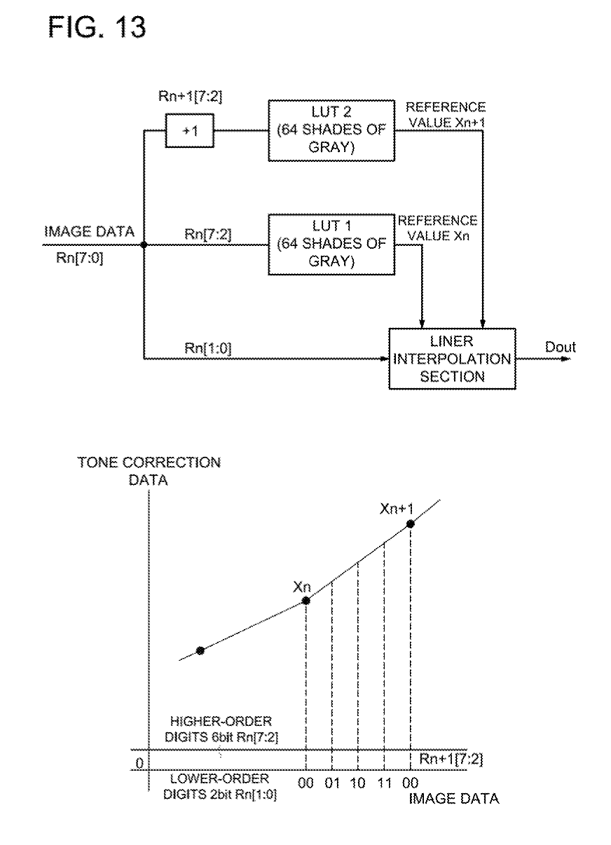

FIG. 14 is another block diagram showing an example of a conventional tone compensation circuit.

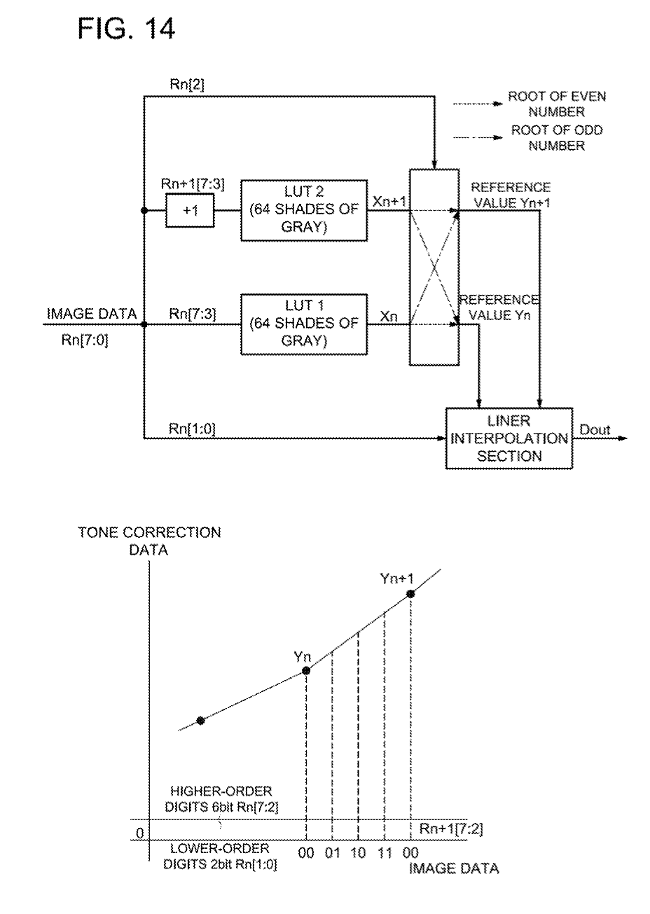

An embodiment of the present invention will be described with reference to the following drawings.

### DETAILED DESCRIPTION OF THE PREFERRED EMBODIMENT

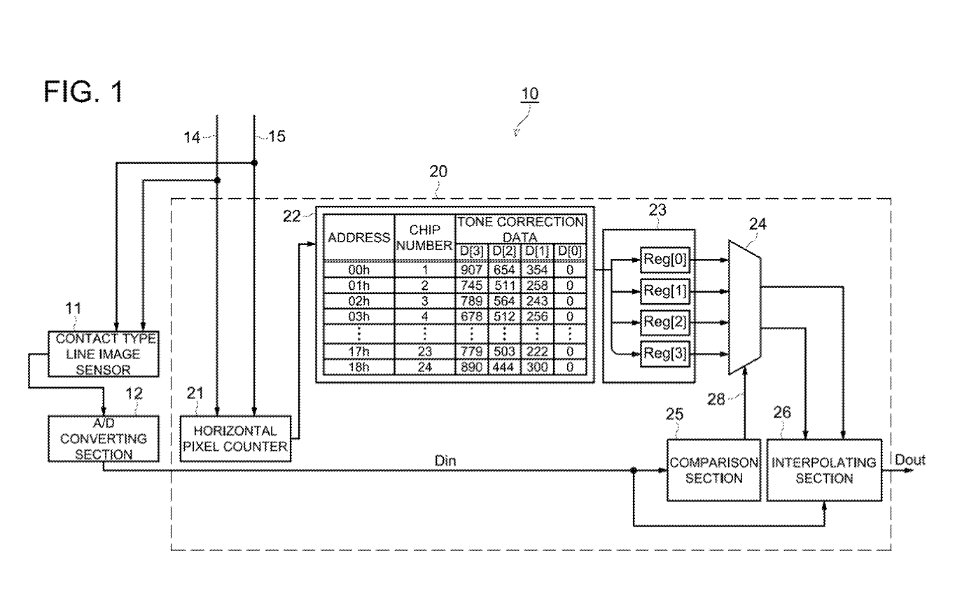

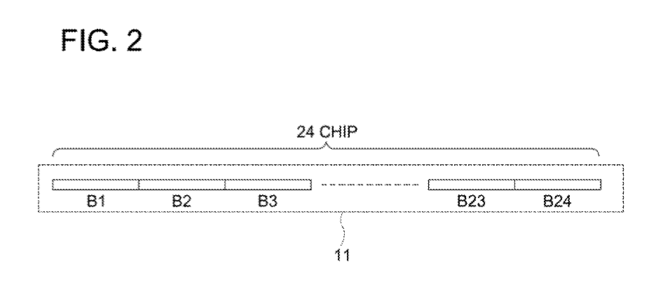

FIG. 1 shows a structure of related portion of an image reading apparatus 10 related to the present inventions. The image reading apparatus 10 is a reading apparatus to read a two dimensional document image where reading operation to read one line of the document in a width direction (horizontal direction) with a contact type line image sensor 11 is repeated while the contact type image line sensor 11 is relatively moved in a longitudinal direction (vertical direction) of the document. Since the contact type line image sensor 11 representing imaging section reads the document in contact with the document, it physically has almost the same width as that of document. Thus, as FIG. 2 shows, the contact type line image sensor 11 is configured by arraying a plurality of sensor chips B having a plurality of imaging elements in a line. The contact type line image sensor 11 of the present embodiment is an image sensor where 24 sensor chips B1-B24 are arrayed in a line. Each sensor chips B is a CCD (Charge Coupled Device) image sensor.

Getting back to FIG. 1, to continue the description, the image reading apparatus 10 is provided with the contact type line image sensor 11 as above, an A/D conversion section 12 to convert an analogue image signal outputted from the contact type line image sensor 11 into image data quantized at a prescribed tone quantity and a tone characteristic correction section 20 to correct tone of an image data outputted from the A/D conversion section 12.

To the contact type line image sensor 11, a clock signal 14 and a horizontal synchronizing signal 15 are inputted. When the horizontal synchronizing signal 15 is inputted to the contact type line image sensor 11, the analogue image signals for respective pixels are sequentially outputted synchronized with input of the clock signal 14. Here the analogue image signals are outputted in order of the sensor chips B1, B2, B3 . . . , B23 and B24.

The A/D conversion section 12 quantizes the analogue image signals outputted sequentially from the contact type line image sensor 11 synchronized with the clock signal 14 and sequentially converts into the digital image data expressing brightness of each pixel by 10 bits to output.

The tone characteristic correction section 20 is provided with a look-up table 22 representing a corrected data memory section to memorize the tone correction data for each sensor chip B which configures the contact type line image sensor 11, a horizontal pixel counter 21 to output a read out address value to the look-up table 22, and a holding register 23 to temporally hold the tone correction data read out from the look-up table 22. Further, a selector 24 to select two pieces of data in the tone correction data outputted from the holding register 23, a comparison section 25 to output a selection signal 28 to the selector 24 and an interpolating section 26 representing a correction section to linearly interpolate two pieces of tone correction data outputted form the selector 24 to perform tone interpolating of the image data.

To the horizontal pixel counter 21, the clock signal 14 and the horizontal synchronizing signal 15 are inputted. An output value from the horizontal pixel counter 21 is inputted to the look-up table 22 as an address value. An initial value of the output value from the horizontal pixel counter 21 is zero. The horizontal pixel counter 21 confirms a leading end of each line by detecting a rising edge of the horizontal synchronizing signal 15, starts counting the clock signal 14 from a time point where the leading edge of each line is confirmed, and increments the output value by one, each time the clock signals 14 equivalent to the quantity pixel of one sensor chip B is counted. Also, the horizontal pixel counter 21 recognizes end of each line by detecting a falling edge of the horizontal synchronizing signal 15 and resets the output value to zero at a time point when an end of each line is recognized.

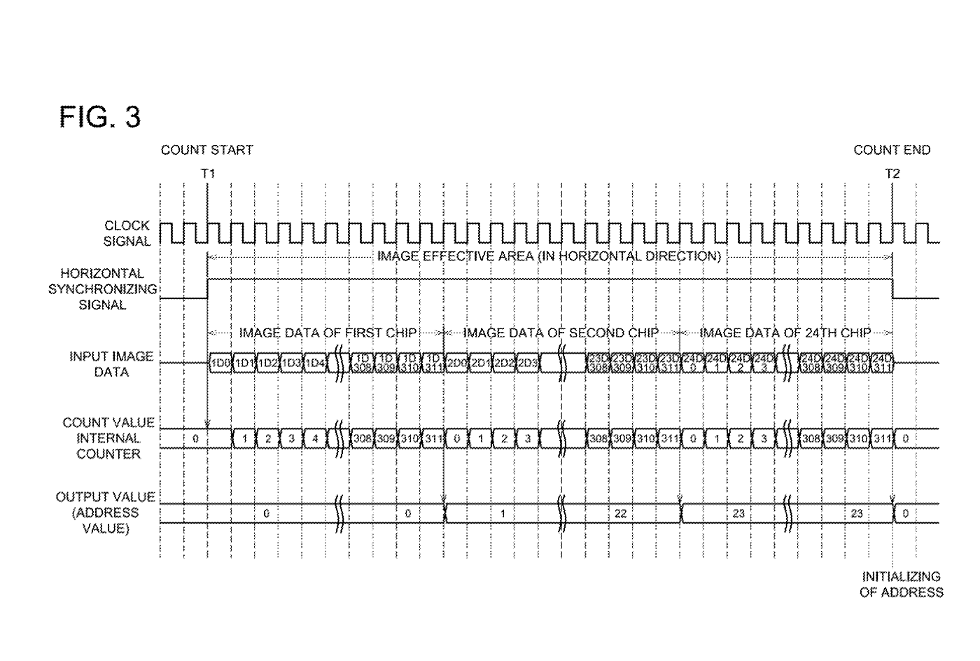

FIG. 3 is a timing chart showing relationships between the clock signal 14, the horizontal synchronizing signal 15, the image data (hereinafter called input image data) inputted from the A/D converting section 12 to the tone characteristic correction section 20, the counter value of an internal counter of a horizontal pixel counter 21 and an output value of the horizontal pixels counter 21 to be an address value for the look-up table 22. In this example, the initial value of the output value is zero. Quantity of the pixels in one sensor chip B is 312. The horizontal pixel counter 21 increments the output value by one, every time the count of the clock signal 14 reaches to 312 of the quantity of the pixels from a time point T1 of the rising edge of the horizontal synchronizing signal 15.

Namely, while the image data of a first sensor chip B1 from the line leading end is toeing inputted to the tone characteristic correction section 20, the output of the horizontal pixel counter 21 becomes zero, and while the image data of a second sensor chip B2 from the line leading end is being inputted to the tone characteristic correction section 20, the output of the horizontal pixel counter 21 becomes one, and then while the image data of a third sensor chip B3 from the line leading end is being inputted to the tone characteristic correction section 20, the output of the horizontal pixel counter 21 becomes two. In this way, every time the sensor chip B representing an output source of the input image data is changed, the output value of the horizontal pixel counter 21 is incremented sequentially, then when input of the image data of a 24th sensor chip B24 is completed, and at a time point T2 when the horizontal synchronizing signal 15 falls the output value thereof is reset to zero.

Meanwhile, the timing chart shown in FIG. 3 does not use the holding register 23 and is adaptable for a case where the output of the look-up table 22 is inputted directly to the selector 24. In case of a configuration where the output of the look-up table 22 is held in the holding register 23, the output value (address value) of the horizontal pixel counter 21 is counted up one clock earlier than the one shown in FIG. 3.

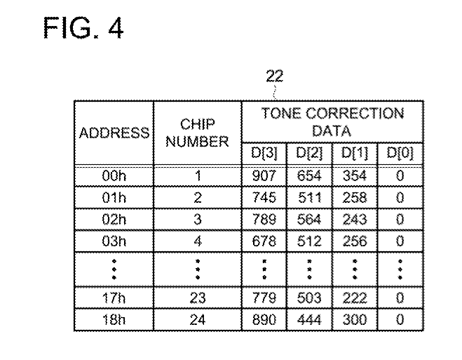

The look-up table 22 is a memory which in advance memorizes the tone correction data for each sensor chip B configuring the contact type line image sensor 11. The look-up table 22 is configured with a general purpose semiconductor memory. FIG. 4 shows an example of memory contents in the look-up table 22. The look-up table 22 memorized a set of the tone correction data where the tone correction data having a prescribed number of tonal steps less than that of the image data inputted from A/D conversion section 12 is combined in a set for each sensor chip B.

For example, in case the input image data form the A/D conversion section 12 is of 1024 tonal steps, for one sensor chip B, the tone correction data (D[3], D[2], D[1] and D[0]) related to four reference points with intervals of 256 tonal steps are memorized as one set. In the look-up table 22, for each address, the tone correction data of one set of reference points in respect to one sensor chip B is memorized. In FIG. 4, the tone correction data of four points in respect to the sensor chip B having chip number N is memorized in an address (N-1). For example, in address 0, one set of four points tone correction data in respect to the sensor chip B1, in address 1, one set of four points tone correction data in respect to the sensor chip B2, in address 2, one set of four points tone correction data in respect to the sensor chip B3, . . . and in address 23, one set of four points tone correction data in respect to the sensor chip B24, are memorized.

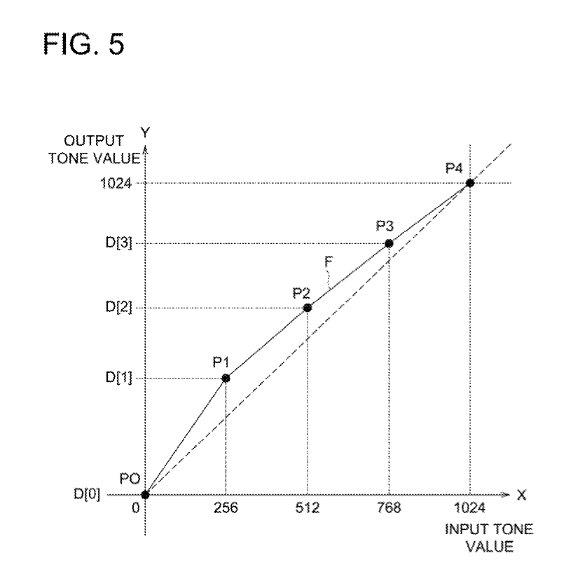

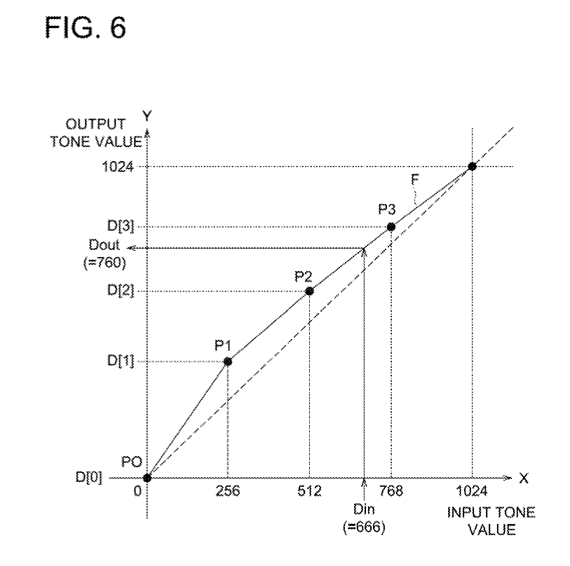

FIG. 5 shows a corrected tone characteristic F obtained by linearly interpolating the tone correction data, and FIG. 6 shows a view where a tone value (input tone value) is processed by tone correction using the corrected tone characteristic F after linear interpolating. In each graph in FIG. 5 and FIG. 6, a X axis is assigned as the input tone value and a Y axis is assigned as the output tone value. An arbitrary point on the graph is expressed by coordinate system (x, y). In FIG. 5, four reference points to obtain the tone correction data are point P0 of (0,D[0]}, P1 of (256,D[1]), P2 of (512,D[2]), and P3 of (768,D[3]). In this example, the distance between four reference points P0-P3 in x coordinate (interpolating tone distance) is 256 tonal steps. The corrected tone characteristic F is configured by connecting these four reference points P0-P3 and P4 having coordinate (1024, 1024). In the look-up table 22, Y coordinate value (D[0], D[1], D[2] and D[3]) for each of reference points P0-P3 are memorized. Meanwhile, Y coordinate value of point P4 can be memorized in the look-up table 22.

A corrected output tone value Dₒᵤₜ after linear interpolation in respect to an arbitrary input tone value Dᵢₙ is determined by calculating the following formula (1):

Dₒᵤₜ=(D[n](P(n+1)x−Din)−D[n+1](Din−Pnx))/(P(n+1)x−Pnx)

Here, Pnx is a X coordinate value of the reference point Pn, and is in a relation of Pnx≦Din<P(n+1)X

For example, a corrected output tone value Dₒᵤₜ(=760) in respect to an input tone value Dᵢₙ(=666) shown in FIG. 6, is obtained by calculating Dₒᵤₜ=(D[2](768−Din)+D[3](Dᵢₙ−512))/256.

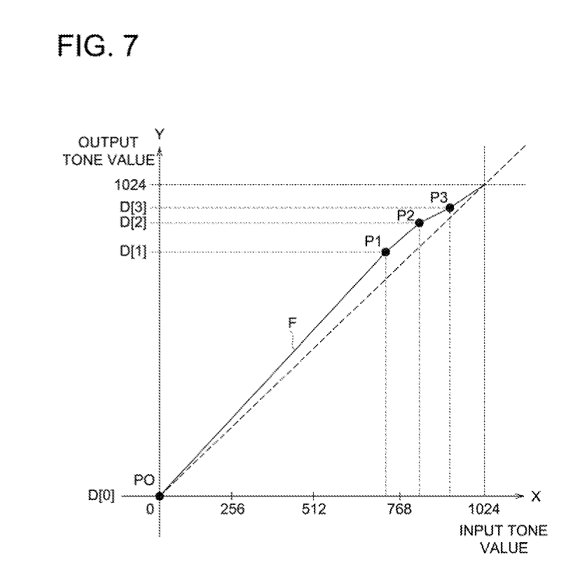

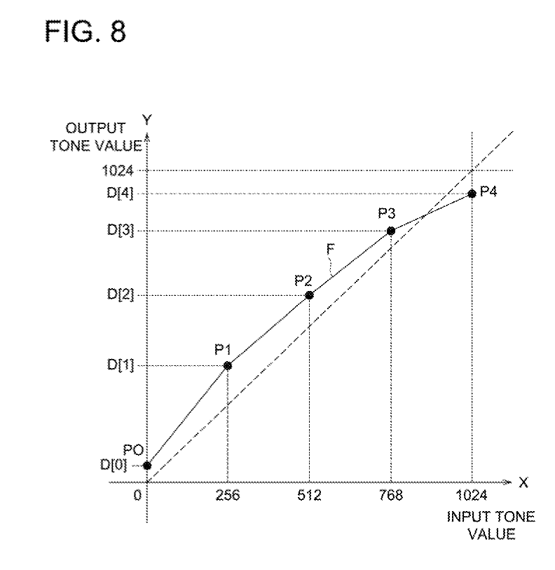

The distance (interpolating tone distance) of X coordinate value of each reference point P0-P3 to obtain the tone correction data D[0]-D[3] is not necessary to be set in equal distances in respect to the input tone value. For example, as FIG. 7 shows, it can be configured to be dense at a high brightness side to improve accuracy of interpolating at the high brightness side. Also, as FIG. 8 shows, when input tone values (X coordinate values) are zero and 1024 (a maximum value +1), there can he a configuration where the tone correction data D[0] and D[4] for the reference points PQ and P4 are held in the look-up table 22 so as to obtain an offset correction tone characteristic F.

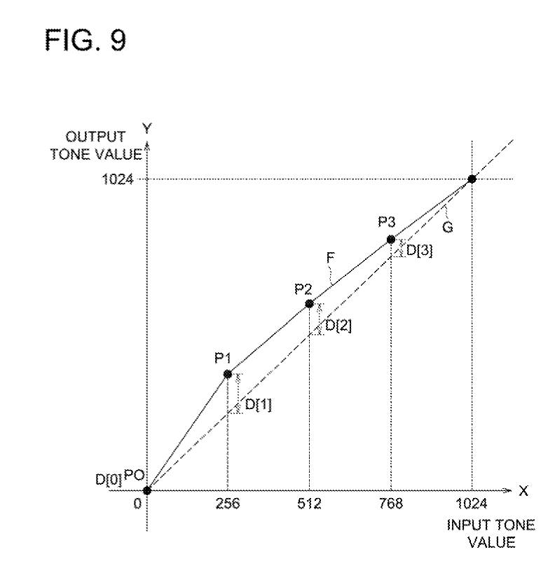

Further, as FIG. 9 shows, there can be a configuration where as the correction data (D[o], D[1], D[2] and D[3]), only differences from a standard tone characteristic values are held so as to reduce the capacity of the memory required for memorizing the tone correction data. For example, by assigning the standard tone characteristic to a straight line G which goes through two points (0,0) and (1024,1024), the difference from the straight line G is held as the tone correction data. Under an assumption where the difference is within ±127, the difference can be expressed by 8 bits, thus an amount of the tone correction data can be reduced. Meanwhile, in case the difference is the tone correction data, the calculation of an equation is carried out after the difference is returned to be an original value in the interpolating section 26.

Getting back to FIG. 1 to continue the description. When an input of an address value from the horizontal pixel counter 21, is received, the look up table 22 outputs the tone correction data D[0]-D[3] for one sensor chip corresponding to the address value at one time.

The holding register 23 is a register to temporally hold the tone correction data outputted from the look-up table 22. In the present example, the holding register 23 is configured with four registers corresponding to the tone correction data D[0]-D[3]. An output from the holding register 23 is inputted to the selector 24.

The selector 24 is a circuit to select two pieces of data among four pieces of tone correction data outputted from the holding register 23. The comparison section 25 is a circuit to output a selection signal 28 to the selector 24. To the comparison section 25, the image data outputted from the A/D conversion section 12 is inputted. The selector 25 compares tone values {brightness values) Dᵢₙ of inputted image data with X coordinate values P0x, P1x, P2X, and P3x of each reference points P0-P3 corresponding to the tone-correction data D[0]-D[3] and judges that between which X coordinate values of two points, the inputted two pieces of tone correction data exist, and then outputs a selection signal 28 so that the selector 24 selects the two pieces of judged tone correction data.

For example, in case the look-up table 22 memorizes the tone correction data corresponding to the reference points P0-P3 shown in FIG. 5, if the tone value Din of the inputted imaged data is 0≦Din<255, D[0] and D[1] are selectively outputted from the selector 24, if 256≦Din<512, D[1] and D[2] are selectively outputted, if 512≦Din<768, D[2] and D[3] are selectively outputted, and if 768≦Din, D[3] and a fixed value of 1024 held in the selector 24 are selectively outputted.

Meanwhile, in case the tone correction data D[4] corresponding to the point P4 is further memorized in the look-up table 22, the holding register 23 holds the tone correction data D[0]-D[4] outputted from the look-up table 22 and the selector 24 selectively outputs D[4] instead of the aforesaid fixed value.

The interpolating section 26 carries out the calculation (liner interpolation calculation) of the above described equation (1) using the tone correction data of two points outputted from the selector 24 and the tone value Din of the inputted image data to output the corrected output tone value Dₒᵤₜ.

Next, operation of the tone characteristic correction section 20 is described.

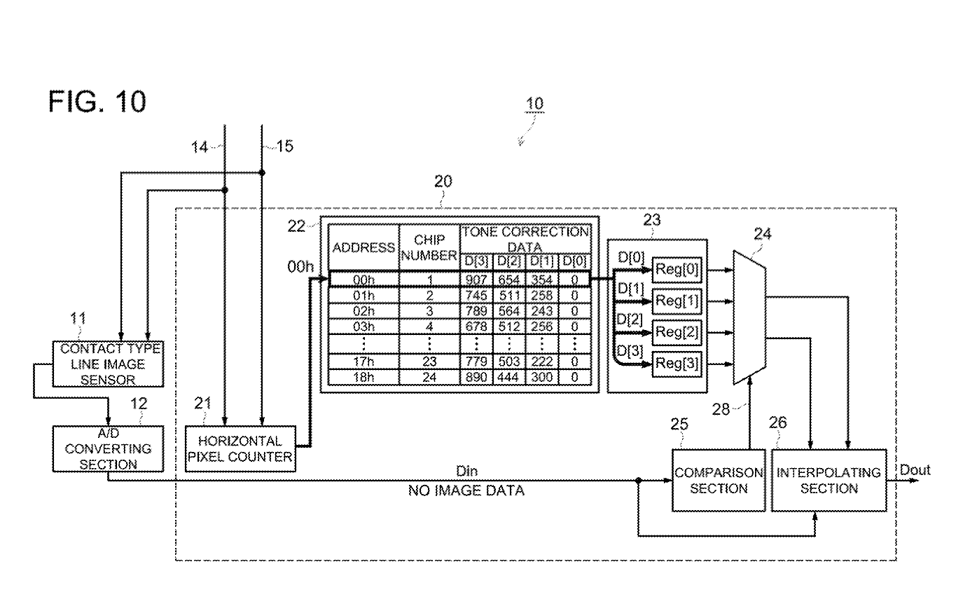

Before the image data of each line head is inputted (at least one clock earlier), address 00h is outputted from the horizontal pixel counter 21 and as FIG. 10 shows, one set of tone correction data D[0] to D[3] corresponding to the sensor chip B1 is read out from the look-up table 22 and held in the holding register 23.

Thereafter, when the horizontal synchronizing signal 15 rises, for each clock signal 14, the image data by pixel is sequentially inputted. When this occurs, the comparison section 25 outputs the selection signal 28 corresponding to tone value Dᵢₙ of the inputted image data and the selector 24 selectively outputs the tone correction data of two reference points according to the selection signal 28. The two points to be selected are the adjacent two points Pn and P(n+1) in a relation that the X coordinate value Pnx≦Dᵢₙ<P(N+1)x.

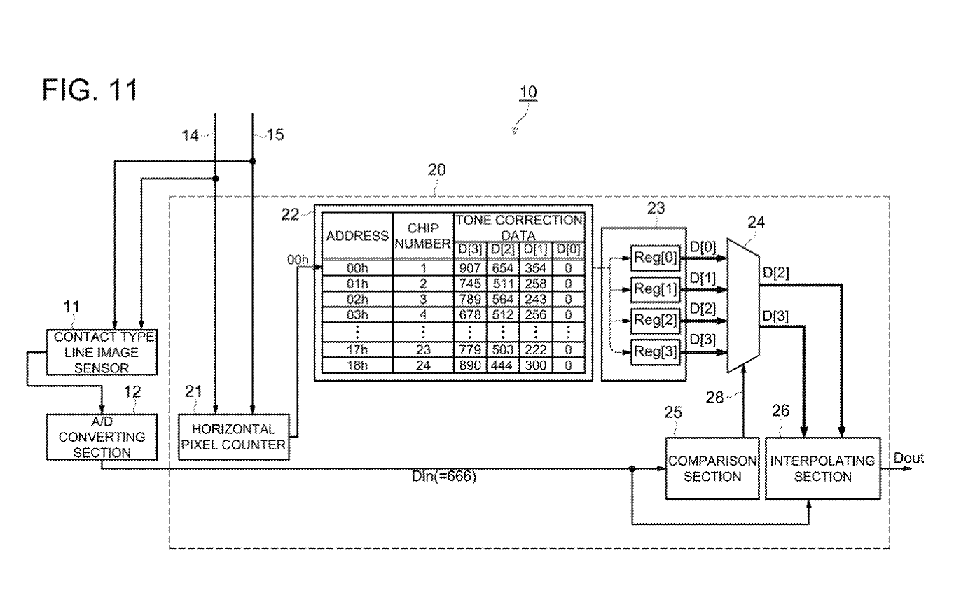

The interpolating section 26 carries out linier interpolation calculation with the above equation (1) based on the tone correction data of the two points outputted from the selector 24 and outputs a calculation result of the corrected output tone value Dₒᵤₜ as an image data which has been corrected by tone correction. An example shown in FIG. 11 describes operation when the input image data having the tone value of 666 is inputted, in a state where the tone correction data of one set of four points in respect to the sensor chip B1 is held in the holding register 23. As FIG. 6 shows, since the tone value 666 exists between a X coordinate value 512 of the point P2 and a X coordinate value 768 of the point P3, the selector 24 selectively outputs the tone correction data D[2](tone value 654) corresponding to the point P2 and the tone correction data D[3](tone value 907) corresponding to the point P3. The interpolating section 26 executes liner interpolation calculation using these tone correction data D[2] and D[3] and output the corrected output tone value Dₒᵤₜ (tone value 760) as an image data which has been corrected by tone correction.

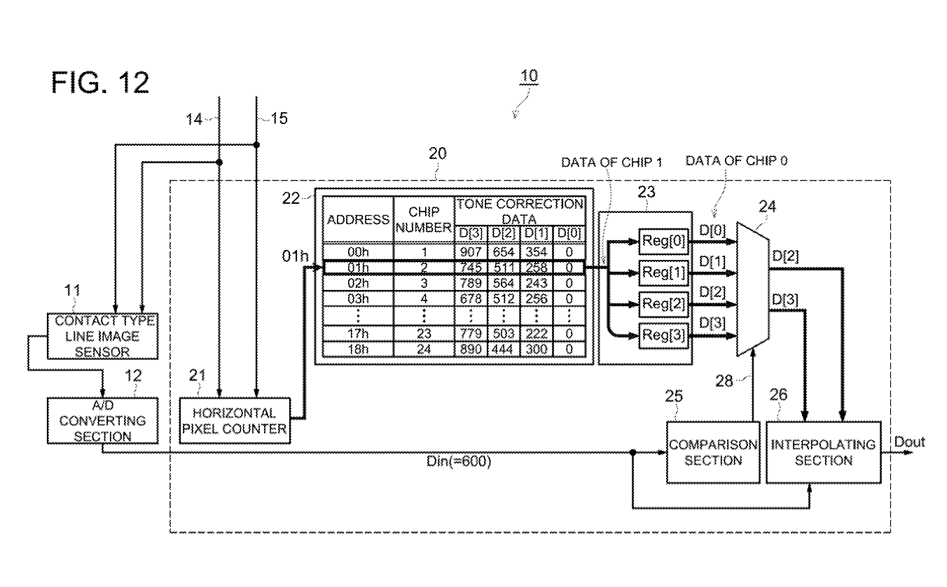

FIG. 12 shows operation when a final pixel of the sensor chip B1 is processed. In this process, the address value from the horizontal pixel counter 21 changes into an address value 01h indicating the sensor chip B2, and a set of tone correction data D[0]-D[3] corresponding to the sensor chip B2 is read out from the look-up table 22. While the final pixel is being processed, one set of tone correction data D[0]-D[3] corresponding to the sensor chip B1 is held in the holding register 23, and in the same manner as described in FIG. 11, the tone correction data of two points are selected, then based on the tone correction data of two points selected, liner interpolation calculation is executed by interpolating section 26, thus the corrected output tone value Dₒᵤₜ (tone value 760) is outputted as the corrected image data by tone correction of the final pixel of the sensor chip B1.

Meanwhile, when a next clock signal 14 is inputted, the look-up table 22 outputs one set of tone correction data D[0]-D[3] corresponding to the sensor chip B2, and the holding register 23 holds the tone correction data D[0]-D[3]. The image data inputted synchronously with the clock signal is a front end pixel of the sensor chip B2, and the image data of the pixel is corrected by tone correction using one set of the tone correction data corresponding to the sensor chip B2 held in the holding register 23.

Afterward, in the same manner, one set of the tone correction data held in the holding register 23 is renewed at a timing where the sensor chips B2, B3 . . . B24 are changed. Thereby, the tone of the image data of each pixel is corrected by liner interpolation calculation using the tone correction data corresponding to the sensor chip B representing the output source thereof.

As the above, the tone characteristic correction section 20 of the image reading apparatus 10 memorizes tone correction data for each sensor chip of the contact type line image sensor 11 in the look-up table 22, and the horizontal pixel counter 21 creates the designation information (address value) for the sensor chip in accordance with the position of the pixel of input image data in the contact type line image sensor 11, so as to correct the tone of the input image data using the tone correction data of one sensor chip read out from the look-tip table 22 with reference to the designation information as the address. Thereby, in accordance with change of sensor chip B representing the output source of input image data, the tone correction data used in tone correction of the image data is automatically changed and the variation of the tone characteristic of each sensor chip B can be corrected.

Also, by memorizing the tone correction data which has less number of tone steps than that of the image data, and by linearly interpolating these tone correction data, even in case that the tone correction data of the plurality of sensor chips is held, the capacity of the memory to hold the data can be suppressed.

In particular, since the holding register 23 holds the tone correction data of one sensor chip, the tone correction data of a plurality of arbitrary points can be obtained immediately. Therefore, for example, even in case a memory requires two or three clocks of the clock signal 14 for reading out data is used to store the look-up table 22, by incrementing the output value (an address value to the look-up table 22) of the horizontal counter 21 before the timing of changing of sensor chip B by the number of the clocks required for reading out, and by renewing the value held in the holding register 23 at the time point where the sensor chip B is changed, the image data can be corrected by tone correction at each clock which has a higher speed than the reading out speed of the tone correction data from the look-up table and high speed processing is possible.

Also, since the tone correction data for one sensor chip can be read out, the tone correction data of three or more points may be obtained immediately among the correction data thereof. Thus, the image data can be corrected by tone correction based on the corrected tone characteristic which is derived by non-linear interpolation using the tone correction data of these three points. Using such non-linear interpolation, even in case the number of tonal steps of the tone correction data is small, since approximation can be carried out accurately compared to linear interpolation, the number of tonal steps of the tone correction data can foe reduced and the memory capacity required to memorize the tone correction data can be reduced. Also, in case non-linear interpolation is possible over a whole tone area at fixed points M such as three points or four points, it is only necessary to memorize the tone correction data for points M for each sensor chip B in the look-up table 22. In this case, as the interpolation is carried out by the fixed tone correction data for points M over the whole tone area, the comparison section 25 and the selector 24 are not necessary.

As above, the embodiment of the present invention has been described with reference to the drawings, specific structure is not limited to the embodiment shown, and it is to be understood that changes and variations may be made without departing from the spirit or scope of the present invention.

For example, though the holding register 23 holds the tone correction data read out from the look-up table 22, in case the tone correction data for one sensor chip can be read out from the look-up table 22 in one action of reading, the output of the look-up table can be directly inputted to the selector 24 without having the holding register 23.

Also, if the tone correction data for one chip can be read out by the address value generated by the horizontal pixel counter 21, the look-up table is not necessary to be memorized in only one memory element and can be memorized in a plurality of memory elements.

Besides the above structures, the contact type line image sensor 11 is not limited to the line image sensor. For example, an image sensor where a plurality of sensor chips are arranged two-dimensionally is possible.

The number of reference points used in interpolation and the number of tonal steps of the image data are not limited to the numbers shown in the examples, they can be arbitrary numbers in accordance with the quality of the image required.

According to the above tone correction apparatus or image reading apparatus related to the present invention, tone correction can be carried out for the output image from imaging section configured by arranging a plurality of sensor chips using respective corrected tone characteristics of the sensor chips while reducing the memory capacity required for holding tone correction data.

What is claimed is:

1. A tone correction apparatus, comprising:
a correction data memory section to memorize tone correction data having a prescribed tonal steps which is less than that of an image data inputted from imaging elements for each sensor chip of an imaging section where a plurality of the sensor chips having a plurality of the imaging elements are arranged;
a designation information generating section to output designation information which designates the sensor chips corresponding to pixel positions of the image data inputted from the imaging elements in the imaging section to the correction data memory section; and
a correction section to read out the tone correction data of one sensor chip designated by the designation information outputted from the designation information generating section from the correction data memory section, to interpolate the tone correction data using not less than 2 pieces of tone correction data in the tone correction data of one sensor chip read out, and to carry out tone correction of the image data inputted based on a result of interpolation thereof.

2. The tone correction apparatus of claim 1, wherein the correction section carries out liner interpolation of the tone correction data.

3. The tone correction apparatus of claim 1, wherein the correction section carries out non-liner interpolation of the tone correction data using two or more pieces of tone correction data.

4. The tone correction apparatus of claim 1, wherein the correction data memory section memorizes a difference of output tone value between the standard tone characteristic and the tone characteristic of each pixel as the tone correction data.

5. The tone correction apparatus of claim 1, wherein the correction section is provided with a holding register to hold the tone correction data of one sensor chip read out form the correction data memory section and carries out tone correction for the image data using the tone correction data held in the holding register.

6. The tone correction apparatus of claim 1, wherein the imaging section is a line image sensor wherein a plurality of the sensor chips are arrayed in a line.

7. The tone correction apparatus of claim 1, wherein the correction data memory section outputs the tone correction data for one sensor chip in one action of reading out.

8. An image reading apparatus, comprising:
an imaging section wherein a plurality of sensor chips having a plurality of imaging elements are arranged;
an A/D conversion section to convert an analogue image signal outputted from the imaging section to digital image data which is quantized to a prescribed tonal steps; and
a tone characteristic correction section to correct tone of the image data outputted from the A/P conversion section, having;
a correction data memory section to memorize tone correction data having a prescribed number of tonal steps less than number of tonal steps of the image data of each sensor chips provided in the imaging section,
a designation information generating section to output designation information which designates the sensor chips corresponding to positions of pixels of the image data in the imaging section to the correction data memory section,
a correction section to read out the tone correction data of one sensor chip designated by the designation information outputted from the designation information generating section from the correction data memory section, to interpolate the tone correction data using not less than 2 pieces of tone correction data in the tone correction data of one sensor chip read out, and to carry out tone correction of the image data inputted based on a result of interpolation thereof.

9. The image reading apparatus of claim 8, wherein the correction section linearly interpolates the tone correction data.

10. The image reading apparatus of claim 8, wherein the correction section non-linearly interpolates the tone correction data using three or more pieces of toner correction data.

11. The tone correction apparatus of claim 8, wherein the correction data memory section memorizes a difference of output tone value between the standard tone characteristic and the tone characteristic of each pixel as the tone correction data.

12. The image reading apparatus of claim 8, wherein there is provided a holding register to hold tone correction data of one sensor chip read out form the correction data memory section and the correction section carries out tone correction for the image data using the tone correction data held in the holding register.

13. The image reading apparatus of claim 8, wherein the imaging section is a line image sensor wherein a plurality of the sensor chips are arrayed in a line.

14. The image reading apparatus of claim 8, wherein the correction data memory section outputs the tone correction data of one sensor chip in one action of reading out.
